(19) United States
(12) Patent Application Publication
(10) Pub. No.: US 2007/0285181 A1
(43) Pub. Date: Dec. 13, 2007

(54) MULTI-MODE OPEN-LOOP TYPE CLOCK EXTRACTION APPARATUS

(75) Inventors: Sang Kyu LIM, Daejeon (KR); Sang Soo LEE, Daejeon (KR); Hyun Jae LEE, Daejeon (KR); Je Soo KO, Daejeon (KR)

Correspondence Address: LOWE HAUPTMAN HAM & BERNER, LLP, 1700 DIAGONAL ROAD, SUITE 300, ALEXANDRIA, VA, 22314, US

(73) Assignee: Electronics & Telecommunications Research Institute, Daejeon (KR)

(21) Appl. No.: 11/745,750

(22) Filed: May 8, 2007

(30) Foreign Application Priority Data
May 23, 2006 (KR) 10-2006-46214
Sep. 4, 2006 (KR) 10-2006-84841

(51) Int. Cl. H03B 1/00

(52) U.S. Cl. 331/74

(57) ABSTRACT

Provided is a multi-mode open-loop type clock extraction apparatus. In the apparatus, a power divider block divides an input data signal into two data signals. A first band-pass filter block and a second band-pass filter block extract a first clock frequency component or a second clock frequency component contained in the data signal output from the power divider. A first amplifier block and a second amplifier block amplify the first clock frequency component and the second clock frequency component respectively. Accordingly, it is possible to extract the respective clock signals corresponding to N data rates from the N data signals with various data rates using a single clock extraction apparatus.

### CLAIM OF PRIORITY

This application claims the benefit of Korean Patent Application No. 10-2006-46214 filed on May 23, 2006, and Korean Patent Application No. 10-2006-84841 filed on Sep. 4, 2006, in the Korean Intellectual Property Office, the disclosure of which is incorporated herein by reference.

### BACKGROUND OF THE INVENTION

1. Field of the Invention

The present invention relates to an optical transmission system, more particularly, to a clock extraction apparatus for recovering a clock signal from incoming data stream at a receiver side in an optical transmission system.

2. Description of the Related Art

In general, a receiver side of an optical transmission system needs a clock extraction device (or a clock recovery device) that extracts a clock signal from incoming data stream because a receiver side performs the data regeneration and de-multiplexing operation into the tributary signals using the recovered signal.

This clock extraction device can be implemented in various types depending on data rates, the types of transmission signals, and the methods of constructing a circuit. Among a variety of clock extraction devices, a clock extraction device using an electrical passive filter is called a passive (or open-loop type) clock extraction device. The configuration of a conventional open-loop type clock extraction device will be described with reference to FIGS. 1 and 2.

FIG. 1 is a block diagram of a conventional open-loop type clock extraction device that extracts a clock signal from non-return to zero (NRZ) data signals. FIG. 2 is a block diagram of a conventional open-loop type clock extraction device that extracts a clock signal from return to zero (RZ) data signals.

Unlike the clock extraction device illustrated in FIG. 2, the open-loop type clock extraction device illustrated in FIG. 1 includes a nonlinear circuit block 100 for generating a clock frequency component from NRZ data signals that does not contain a clock frequency component.

The clock extraction devices illustrated in FIGS. 1 and 2 include: an electrical filter block 110 or 200 for filtering only a specific clock frequency component from the signals containing a clock frequency component; and a clock amplifier block 120 or 210 for amplifying the clock frequency component extracted from the electrical filter block 110 or 200.

For a data rate of less than several Gbit/s, the electrical filter block 110 or 200 has been implemented by a surface acoustic wave (SAW) filter or a tank circuit using discrete elements such as resistors, inductors, and capacitors. For a data rate of more than several Gbit/s, the electrical filter block 110 or 200 has been realized by a high-Q dielectric resonator filter with good microwave characteristics, because of the difficulty in fabricating a tank circuit or a SAW filter.

The electrical filter block 110 or 200 is fabricated to have a high-Q value (=center frequency/3-dB bandwidth) for a high-quality clock signal, which means that the pass band of a corresponding filter is very narrow. Because the center frequency in a pass band of such a filter is fixed after fabrication, a conventional clock extraction device using the passive filter operates at only one data rate.

Examples of a signal with a data rate of about 40 Gbit/s are an STM-256 signal (39.81312 Gbit/s), a 42.8369 Gbit/s signal, and an OTU-3 signal (43.018413 Gbit/s). The STM-256 signal is obtained by multiplexing four SDH (synchronous digital hierarchy) based STM-64 signals (9.95328 Gbit/s). The 42.8369 Gbit/s signal is obtained by multiplexing four OTH (optical transport hierarchy) based OTU-2 signals (10.709225 Gbit/s). In order to design an optical transmission system supporting two or more kinds of data rates, a clock extraction device or a band-pass filter (BPF) in a receiver using the conventional clock extraction device must be replaced in accordance with a desired data rate.

FIG. 3 is a view illustrating the structure of a dielectric resonator that is used in the conventional open-loop type clock extraction device for a data rate of more than several Gbit/s.

Referring to FIG. 3, the dielectric resonator filter includes a microwave substrate 330, a dielectric resonator 320, an input transmission line 310, an output transmission line 315, and a screw 360 for adjusting a resonant frequency. The dielectric resonator 320 is attached to the top surface of the microwave substrate 330. The input transmission line 310 and the output transmission line 315 are formed on the microwave substrate 330 such that it is electrically or magnetically coupled to the dielectric resonator 320. The screw 360 is attached to the top portion of the dielectric resonator 320 such that the distance between it and the dielectric resonator 320 can be adjusted. The input transmission line 310, the output transmission line 315, the dielectric resonator 320, the microwave substrate 330, and the screw 360 are fixed and protected by a metal case 350. An input connector 300 and an output connector 340 are attached to the outside of the metal case 350 and are connected to the input transmission line 310 and the output transmission line 315, respectively.

In the conventional dielectric resonator filter, the screw 360 is used to adjust the distance between it and the dielectric resonator 320, thereby adjusting the center frequency of the pass band.

The screw 360 mainly functions to adjust a center frequency in a very-narrow pass band, which may deviate during the mounting the dielectric resonator or the manufacturing the dielectric resonator filter, to a desired clock frequency. However, the screw 360 has a very narrow tuning range, thereby not satisfy both of the two data rates that are different by several Gbit/s.

In addition, because the conventional dielectric resonator filter is mounted with coaxial I/O connectors, it has been an obstacle to miniaturization of the clock extraction device into one module.

### SUMMARY OF THE INVENTION

The present invention has been made to solve the foregoing problems of the prior art and it is therefore an object of certain embodiments of the present invention to provide a multi-mode open-loop type clock extraction apparatus which can recover a clock signal corresponding to the data rate from a data signal with varying data rates.

Another object of the present invention is to provide a multi-mode open-loop type clock extraction apparatus that does not has the need to replace a clock extraction apparatus totally or an electrical filter block in the clock extraction apparatus when a data rate needs to be changed in an optical transmission system supporting various transmission rates.

A further object of the present invention is to provide a multi-mode open-loop type clock extraction apparatus that can be fabricated in the shape of a miniaturized module.

According to an aspect of the present invention, there is provided a multi-mode open-loop type clock extraction apparatus including: a power divider block for dividing an input data signal into two data signals; a first band-pass filter block for extracting a first clock frequency component contained in the data signal output from the power divider; a second band-pass filter block for extracting a second clock frequency component contained in the data signal output from the power divider; a first amplifier block for amplifying the first clock frequency component extracted by the first band-pass filter block; and a second amplifier block for amplifying the second clock frequency component extracted by the second band-pass filter block.

The multi-mode open-loop type clock extraction apparatus may further include a nonlinear circuit block for generating, from two types of data signals with different data rates, clock frequency components corresponding to the respective data rates.

The power divider block may be a Wilkinson-type power divider or a resistive T-shaped power divider formed on a microwave substrate. The first band-pass filter block and the second band-pass filter block may be dielectric resonator filters. The first clock amplifier block and the second clock amplifier block may be MMIC amplifiers.

The dielectric resonator filter may include: a base plate; a microwave substrate attached on the top surface of the base plate; an input transmission line and an output transmission line disposed on the top surface of the microwave substrate such that the input/output transmission lines are arranged in a straight line; a disc-type dielectric resonator disposed between the input transmission line and the output transmission line; and a metal cover having a small internal space formed therein and being coupled with the base plate to cover the input transmission line, the output transmission line, and the disc-type dielectric resonator.

The nonlinear circuit block performs exclusively OR logic operation of data signals delayed by different time intervals to generate a clock frequency component from an input NRZ data signal. The time difference between the delayed data signals is set to the half of the average time period of two NRZ input data signals with different data rates, i.e.,

$$\frac{1}{2} ( \frac{{T}_{1} + {T}_{2}}{2} )$$

where T₁ and T₂ are the time periods of the two NRZ input data signals.

Preferably, the respective circuit blocks are implemented on a microwave substrate, the I/O connection therebetween is made by a bonding technique, and all the blocks are packaged into a single module.

According to another aspect of the present invention, there is provided a multi-mode open-loop type clock extraction apparatus including: a 1:N power divider block for dividing one of input data signals with various data rates into N number of data signals, N being a natural number equal to or greater than 2; N number of band-pass filter blocks connected respectively to output ports of the 1:N power divider and having center frequencies in pass-band corresponding to N number of data rates in order to extract the respective clock signals from data signals with N number of data rates; and N number of amplifier blocks connected respectively to the N number of the output ports of band-pass filter blocks to amplify the respective clock signals extracted from the band-pass filter blocks.

The multi-mode open-loop type clock extraction apparatus may further include a nonlinear circuit block for generating, from data signals with various data rates, clock frequency components corresponding to the respective data rates.

It is to be understood that both the foregoing general description and the following detailed description of the present invention are exemplary and explanatory and are intended to provide further explanation of the invention as claimed.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a block diagram of a conventional open-loop type clock extraction device that extracts a clock signal from an NRZ data signal;

FIG. 2 is a block diagram of a conventional open-loop type clock extraction device that extracts a clock signal from an RZ data signal;

FIG. 3 is a view illustrating the structure of a dielectric resonator that is used in a conventional open-loop type clock extraction device;

FIG. 4 is a block diagram of a multi-mode open-loop type clock extraction apparatus for extracting a clock signal from an NRZ data signal, according to a first embodiment of the present invention;

FIG. 5 is a block diagram of a multi-mode open-loop type clock extraction apparatus for extracting a clock signal from an RZ data signal, according to a second embodiment of the present invention;

FIG. 6 is a detailed block diagram of a nonlinear circuit block of the multi-mode open-loop type clock extraction apparatus according to an embodiment of the present invention;

FIG. 7(a) is a graph illustrating the waveform of an NRZ data signal (39.813 Gbit/s) that is input to the nonlinear circuit block illustrated in FIG. 6;

FIG. 7(b) is a graph illustrating the spectrum of a signal (39.813 GHz) that is output from the nonlinear circuit block illustrated in FIG. 6;

FIG. 8(a) is a graph illustrating the waveform of an RZ data signal (42.8369 Gbit/s) that is input to the nonlinear circuit block illustrated in FIG. 6;

FIG. 8(b) is a graph illustrating the spectrum of a signal (42.8369 GHz) that is output from the nonlinear circuit block illustrated in FIG. 6;

FIG. 9 illustrates the structure of a band-pass filter (BPF) block in the multi-mode open-loop type clock extraction apparatus according to an embodiment of the present invention;

FIG. 10 is a circuit diagram of the multi-mode open-loop type clock extraction apparatus according to an embodiment of the present invention; and

FIGS. 11A through 11C are graphs illustrating the results of testing the multi-mode open-loop type clock extraction apparatus according to the present invention.

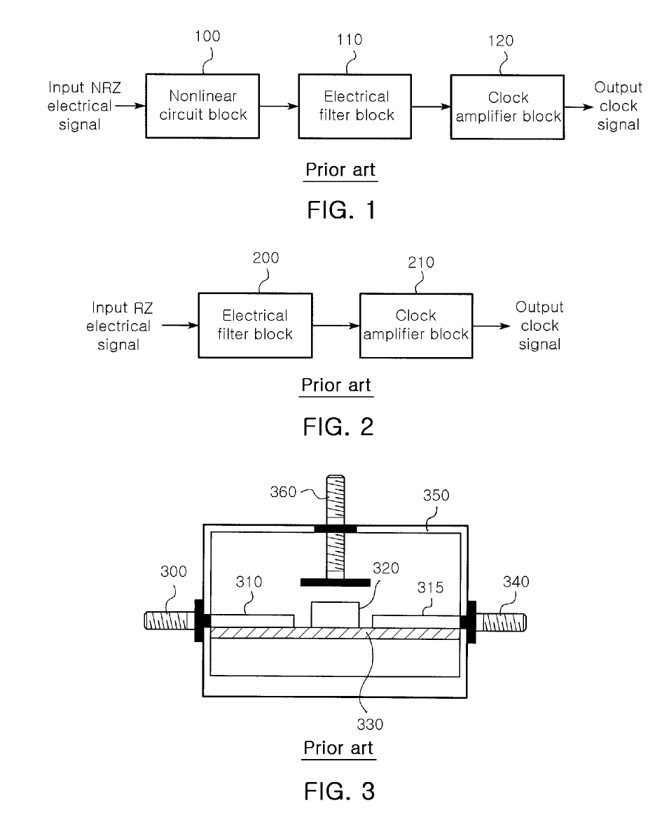

### DETAILED DESCRIPTION OF THE PREFERRED EMBODIMENT

The present invention will now be described more fully hereinafter with reference to the accompanying drawings, in which preferred embodiments of the invention are shown.

In the following description of the embodiments of the present invention, detailed descriptions about well-known functions and configurations incorporated herein will be omitted if they are deemed to obscure the subject matter of the present invention. In addition, like reference numerals in the drawings denote like elements.

According to the present invention, one of two data signal with different data rates is divided by a power divider into two data signals. The divided two data signals are input to band-pass filters with center frequencies corresponding to the different data rates. Accordingly, it is possible to selectively obtain clock signals corresponding to the different data rates using one clock extraction apparatus. The configuration of a multi-mode open-loop type clock extraction apparatus according to the present invention may vary depending on whether an input data signal is an NRZ signal or an RZ signal.

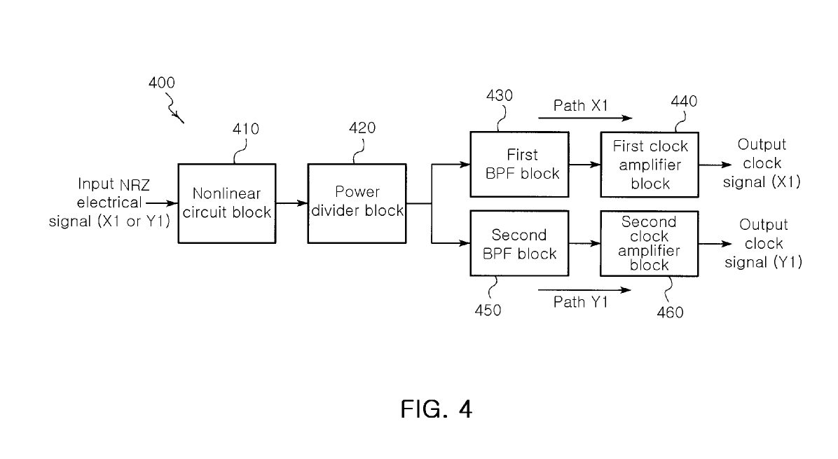

FIG. 4 is a block diagram of a multi-mode open-loop type clock extraction apparatus according to a first embodiment of the present invention. The multi-mode open-loop type clock extraction apparatus illustrated in FIG. 4 aims at processing an NRZ data signal that does not contain a clock frequency component.

Referring to FIG. 4, the multi-mode open-loop type clock extraction apparatus includes a nonlinear circuit block 410, a power divider block 420, a first band-pass filter block 430, a first clock amplifier block 440, a second band-pass filter block 450, and a second clock amplifier block 460.

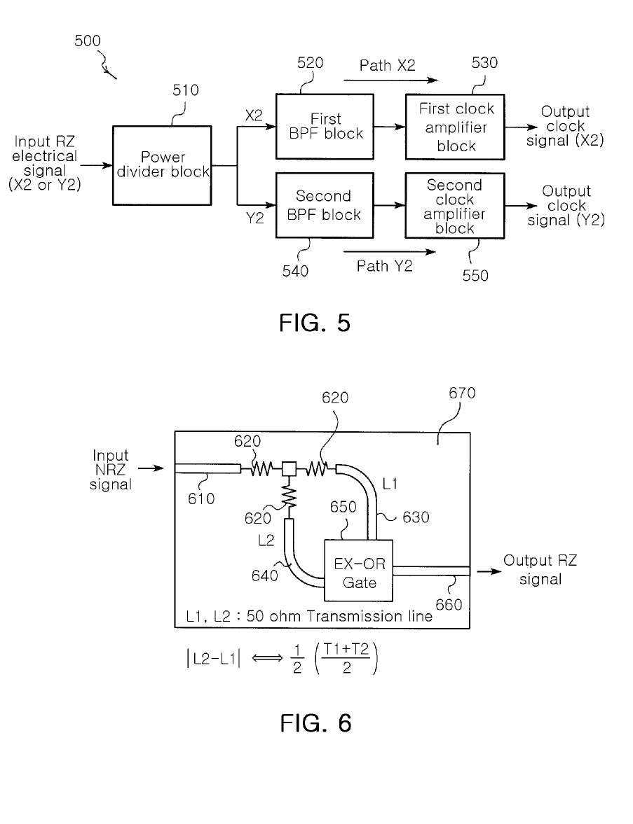

FIG. 5 is a block diagram of a multi-mode open-loop type clock extraction apparatus according to a second embodiment of the present invention. The multi-mode open-loop type clock extraction apparatus illustrated in FIG. 5 aims at extracting a clock signal from an RZ data signal that contains a clock frequency component.

Referring to FIG. 5, the multi-mode open-loop type clock extraction apparatus includes a power divider block 510, a first band-pass filter block 520, a first clock amplifier block 530, a second band-pass filter block 540, and a second clock amplifier block 550. That is, because a clock frequency component is contained in an input RZ data signal, the multi-mode open-loop type clock extraction apparatus according to the second embodiment does not include a nonlinear circuit block unlike the multi-mode open-loop type clock extraction apparatus according to the first embodiment.

The configurations and functions of the respective blocks will now be described in detail.

When an electrical input signal is an NRZ data signal not containing a clock frequency component, the nonlinear circuit block 410 converts the data signal into a signal containing a clock frequency component. Because the multi-mode open-loop type clock extraction apparatus must be able to process data signals having different data rates, the nonlinear circuit block 410 must generate clock frequency components corresponding respectively to data signals having different data rates. To this end, the nonlinear circuit block 410 performs exclusive OR logic operation of data signals delayed by different time intervals, thereby generating a clock frequency component from an input NRZ data signal. At this point, the delay difference between the delayed data signals is set to the half of the average period of two NRZ input data signals of different data rates, i.e.,

$$\frac{1}{2} ( \frac{{T}_{1} + {T}_{2}}{2} )$$

(where T₁ and T₂ are the periods of the two NRZ input data signals).

FIG. 6 is a detailed block diagram of the nonlinear circuit block 410 according to an embodiment of the present invention.

Referring to FIG. 6, the nonlinear circuit block 410 includes an input transmission line 610, a power divider, a first transmission line 630, a second transmission line 640, an exclusive-OR(EX-OR) device 650, and an output transmission line 660. Two NRZ data signals of different periods are input to the input transmission line 610. The power divider includes three identical resistors 620 and divides an input signal into two identical data signals. The first and second transmission lines 630 and 640 have the same length, and transmit the two output data signals of the power divider to the two input ports of the EX-OR device 650. The EX-OR device 650 performs exclusive OR logic operation of two data signals that are received from the power divider through the first and second transmission lines 630 and 640.

At this point, the first and second transmission lines 630 and 640 delay two identical NRZ data signals from the power divider by different time intervals such that that the delay difference between the delayed data signals is equal to the half of the average period of two NRZ input data signals of different data rates (i.e.,

$$\frac{1}{2} ( \frac{{T}_{1} + {T}_{2}}{2} ) ,$$

where T₁ and T₂ are the periods of the two NRZ input data signals). To this end, the length L₁ of the first transmission line 630 and the length L₂ of the second transmission line 640 are set to satisfy Equation (1) below.

$$\vert {L}_{2} - {L}_{1} \vert ⇔ \frac{1}{2} ( \frac{{T}_{1} + {T}_{2}}{2} )$$

In addition, the resistance of each of the resistors 620 in the power divider is set to the third of the characteristic impedance of a transmission line. That is, when the transmission line has a characteristic impedance of 50Ω, the resistance of the resistor 620 is set to 16˜17Ω.

The above-described element of the nonlinear circuit block 410 is formed on a microwave substrate 670, and may be packaged into one module with I/O connectors. For miniaturization of the multi-mode open-loop type clock extraction apparatus, it is preferable that the output transmission line 660 of the nonlinear circuit block 410 is bonded and connected to an input transmission line of the power divider 420.

When an NRZ data signal with a predetermined period (T₁ or T₂) is applied to the input transmission line 610, the nonlinear circuit block 410 divides the NRZ data signal into two identical data signals using the three resistors 620 of the power divider and applies the two identical data signals respectively to the first and second transmission lines 630 and 640.

While passing through the first and second transmission lines 630 and 640, the two identical data are delayed by different time intervals corresponding to the lengths of the first and second transmission lines 630 and 640 and thus have a phase difference therebetween. The delayed data signals are EX-ORed by the EX-OR device 650, and thus clock frequency components corresponding to the respective data signals are generated and output through the output transmission line 660.

In addition, an amplifier may be inserted at an output side of the EX-OR device 650 so that the nonlinear circuit block 410 can amplify the generated clock frequency components. This is done to amplify the output clock frequency components from the EX-OR device 650 to a desired amplitude when the output clock frequency components are small in amplitude.

An experiment was performed to test the operating characteristics of the nonlinear circuit block 410. In the experiment, a nonlinear circuit block was constructed as illustrated in FIG. 6. Then, a 39.813 Gbit/s NRZ data signal and a 42.8369 Gbit/s NRZ data signal were applied to the constructed nonlinear circuit block so that signals respectively containing clock frequency components corresponding to the applied NRZ data signals could be output from the constructed nonlinear circuit block. Thereafter, the output results were measured to test the operating characteristics of the constructed nonlinear circuit block.

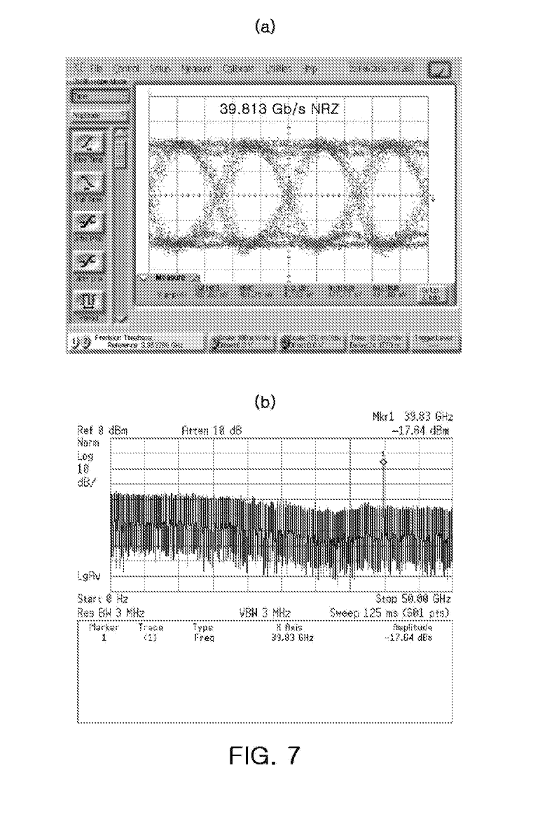

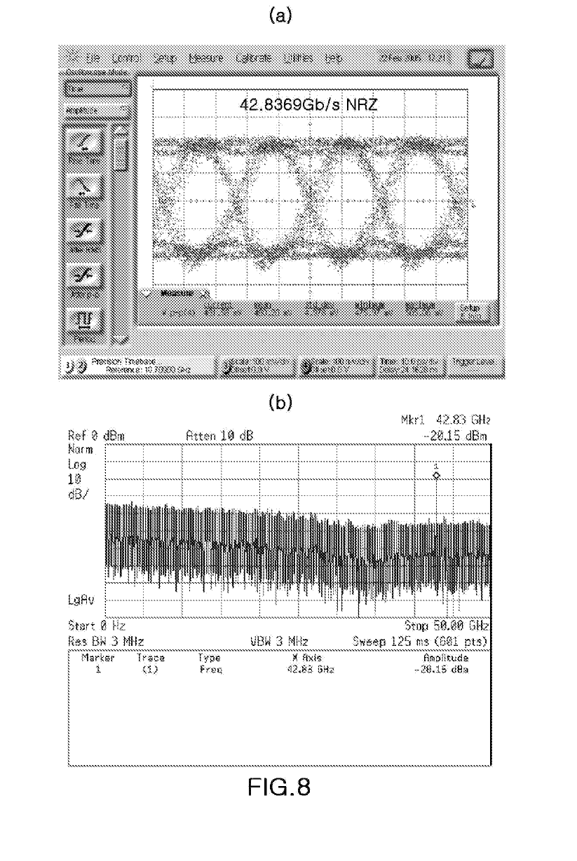

FIGS. 7 and 8 are graphs illustrating the results of the above experiment. When the 39.813 Gbit/s NRZ data signal as illustrated in FIG. 7(a) was applied to the input transmission line 610, output spectrum characteristics as illustrated FIG. 7(b) were obtained from the output transmission line 660. As can be seen from FIG. 7(b), the measured output signal has a frequency of 39.83 GHz and amplitude of −17.64 dBm. There is a slight difference between the frequency (39.83 GHz) of the measured output signal and a clock frequency of 39.813 GHz corresponding to the data rate of an input data signal. Such a slight frequency difference is due to the frequency resolution of a measuring instrument that occurs when the bandwidth of the measuring instrument is set to a wideband mode (0˜50 GHz). When the measuring instrument is set to a narrowband mode, there is no frequency difference.

When the 42.8369 Gbit/s NRZ data signal as illustrated in FIG. 8(a) was applied to the nonlinear circuit block 410, the output spectrum characteristics of the corresponding output signal was measured as illustrated FIG. 8(b). As can be seen from FIG. 8(b), the measured output signal has a frequency of 42.83 GHz and amplitude of −20 dBm.

As can be seen from the above, when the nonlinear circuit block 410 is used in the nonlinear circuit block, the clock frequency components corresponding to the different data rates of the two input data signals can be generated to have an accurate frequency and a good amplitude.

An input NRZ data signal is converted by the nonlinear circuit block 410 and is provided to the power divider block 420. An input RZ data signal is directly provided to the power divider block 510. The power divider block 420 or 510 divides an input signal into two signals and provides the two signals respectively to the first band-pass filter block 430 or 520 and the second band-pass filter block 450 or 540. The power divider is well known in the art and the present invention can use any type of power divider. For miniaturization of the multi-mode open-loop type clock extraction apparatus into a single module, it is preferable that the power divider block 420 or 510 is implemented in the form of a passive device on a microwave substrate and its I/O connection to the front/rear ends is made in a bonding fashion. For example, it is preferable that the power divider block 420 or 510 is a Wilkinson type power divider mountable on a microwave substrate or a resistive T-shaped power divider as in the nonlinear circuit block illustrated in FIG. 6.

The first band-pass filter block 430 or 520 and the second band-pass filter block 450 or 540 are set to be different in a center frequency of a pass band. Thus, only a clock frequency component corresponding to a center frequency of each band-pass filter is extracted from each data signal divided by the power divider block 420 or 510.

More specifically, when the multi-node open-loop type clock extraction apparatus 400 or 500 extracts clock signals from a data signal with a period of T₁ and a data signal with a period of T₂, the center frequency of the first band-pass filter block 430 or 520 and the center frequency of the second band-pass filter block 450 or 540 are

$$\frac{1}{{T}_{1}} and \frac{1}{{T}_{2}} ,$$

respectively. In this case, for extraction of a relatively clean clock signal, it is preferable that the first band-pass filter block 430 or 520 and the second band-pass filter block 450 or 540 are small in pass bandwidth and large in Q value. More preferably, the band-pass filter blocks are implemented on a chip block or a substrate block rather than a module so that is can be integrated.

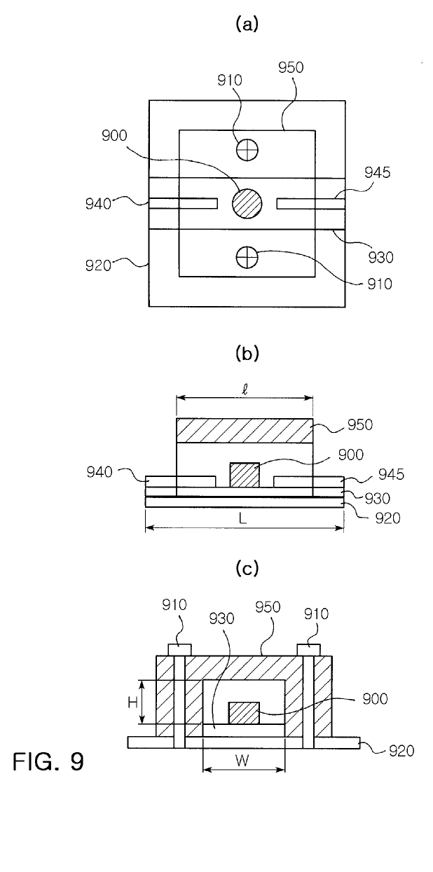

FIG. 9 illustrates the first band-pass filter block 430 or 520 and the second band-pass filter block 450 or 540 according to an embodiment of the present invention. FIG. 9(a) is a top view of the band-pass filter block, FIG. 9(b) is a front view of the band-pass filter block, and FIG. 9(c) is a side sectional view of the band-pass filter block.

Referring to FIG. 9, the band-pass filter block is used to extract a clock frequency component in the multi-mode open-loop type clock extraction apparatus according to the present invention. The band-pass filter block includes a base plate 920, a microwave substrate 930, an input transmission line 940, an output transmission line 945, a disc-type dielectric resonator 900, a metal cover 950, and a coupling screw 910. The base plate 920 is configured to couple the metal cover 950. The microwave substrate 930 is attached to the top surface of the base plate 920. The input transmission line 940 and the output transmission line 945 are disposed on the top surface of the microwave substrate 930 such that they are arranged in a straight line. The disc-type dielectric resonator 900 is disposed between the input transmission line 940 and the output transmission line 945. The metal cover 950 has a small internal space formed therein. The metal cover 950 is coupled with the base plate 920 such that it covers the input transmission line 940, the output transmission line 945, and the disc-type dielectric resonator 900. The coupling screw 910 is configured to couple and fix the base plate 920 and the metal cover 950.

The dielectric resonator 900, the metal cover 950, the input transmission line 940 and the output transmission line 945, which are disposed on the microwave substrate 930, may vary in physical size depending on a desired resonant frequency bandwidth. The following is an embodiment for a frequency band with a resonant frequency of 40 GHz.

The microwave substrate 930 has a dielectric constant of 2.33, a thickness of 0.254 mm, a width W of 0.24 mm (see FIG. 9(c)). The input transmission line 940 and the output transmission line 940 are microstrip transmission lines with a width of 0.37 mm. The length L (in the direction of the transmission line) of the microwave substrate 930 is 14 mm. The disc-type dielectric resonator 900 has a dielectric constant of 30.7, a diameter of 1.6 mm, and a height of 0.64 mm. An internal space from the microwave substrate 930 to the metal cover 950 has a height H of 1.65 mm. The metal cover 950 has a length L of 8 mm.

Unlike the conventional dielectric resonator filter, the band-pass filter block according to the present invention does not include a metal screw for adjusting a resonant frequency. Instead, the adjustment of a resonant frequency is made by adjusting the height of the internal space or the thickness of the dielectric resonator 900. Accordingly, it is possible to prevent a degradation in spurious characteristics, which is cased by insertion of the conventional metal screw for adjusting a resonant frequency.

Preferable, the metal cover 950 has a simple shape of [symbol] . Therefore, the metal cover 950 can be easily fabricated and can be simply attached/detached using the coupling screw.

The band-pass filter blocks 430, 450, 520 and 540 illustrated in FIG. 9 are fabricated in a predetermined structure and detailed conditions depending on a required center frequency. After the band-pass filter blocks 430, 450, 520 and 540 are installed in the multi-mode open-loop type clock extraction apparatus, the height H of the internal space or the thickness of the dielectric resonator 900 may be adjusted for fine adjustment of the resonant frequency.

In addition, because portions of the input/output transmission lines 940 and 945 are exposed outside the metal cover 950, the band-pass filter block is connected to neighbor blocks by direct bonding.

A clock frequency component, extracted by the first band-pass filter block 430 or 520, is amplified by the first clock amplifier block 440 or 530. Likewise, a clock frequency component, extracted by the second band-pass filter block 450 or 540, is amplified by the second clock amplifier block 460 or 550. The first clock amplifier block 440 or 530 and the second amplifier block 460 or 550 may be implemented using any type of amplifier. Preferably, in order to be able to integrate the multi-mode open-loop type clock extraction apparatus, the first clock amplifier block 440 or 530 and the second amplifier block 460 or 550 is implemented using a monolithic microwave IC (MMIC) amplifier. Each of the clock amplifier blocks amplifies a corresponding clock signal in adaptation to the amplitude of a final output signal so that the amplitude of the final output signal can be maintained at a constant value even when the amplitude of the input signal varies within some range. Accordingly, it is preferable that each of the first clock amplifier block 440 or 530 and the second clock amplifier block 460 or 550 is designed to perform an amplifying function only in a corresponding clock frequency domain.

In the multi-mode open-loop type clock extraction apparatus 400 or 500, a signal path is divided into two paths from the power amplifier block 420 or 510.

That is, the first band-pass filter block 430 or 520 is designed to have frequency a characteristic corresponding to a clock frequency of a data signal with a period of T₁ and the second band-pass filter block 450 or 540 is designed to have frequency characteristics corresponding to a clock frequency of a data signal with a period of T₂. In this case, a data signal X1 or X2 with a period T₁ travels along a path X1 or a path X2 and a clock signal is output from the first clock amplifier block 440 or 530. Likewise, a data signal Y1 or Y2 with a period T₂ travels along a path Y1 or a path Y2 and a clock signal is output from the second clock amplifier block 460 or 550.

In order to minimize the power consumption of the multi-mode open-loop type clock extraction apparatus, it is preferable to interrupt a DC power supplied to a clock amplifier block corresponding to a signal path irrelevant to the transmission rate of an input data signal (i.e., a desired clock frequency component.

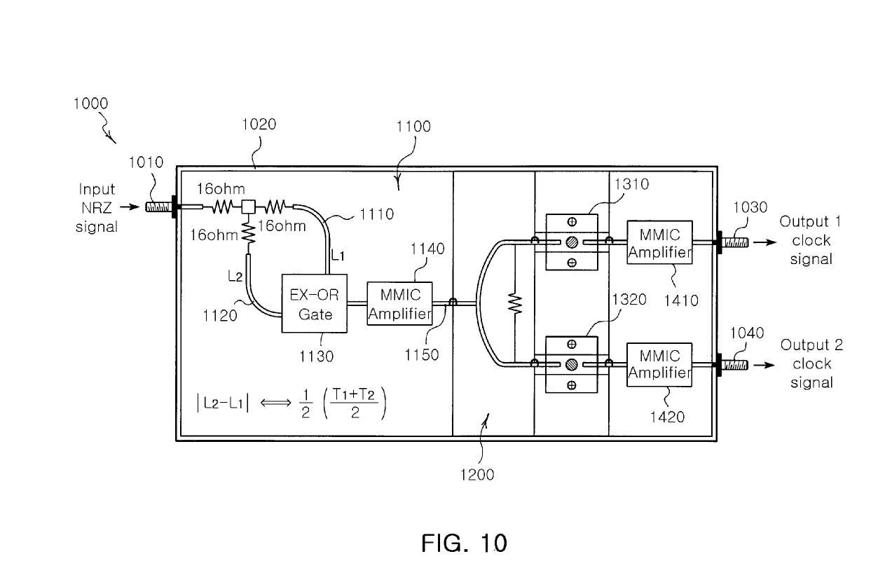

FIG. 10 is a circuit diagram of a multi-mode open-loop type clock extraction apparatus according to an embodiment of the present invention, which extracts a 39.813 GHz clock signal and a 42.8369 GHz clock signal from a 39.813 Gbit/s NRZ electrical signal and a 42.8369 Gbit/s NRZ electrical signal.

Referring to FIG. 10, the multi-mode open-loop type clock extraction apparatus includes a nonlinear circuit block 1100, a power divider 1200, a first band-pass filter block 1310, a second band-pass filter block 1320, a first clock amplifier block 1410, and a second clock amplifier block 1420.

The above blocks are implemented on a microwave substrate and then the I/O connection therebetween is made by a bonding scheme. Thereafter, the resulting structure is packaged by a metal case 1020 into a single module. Then, an input transmission line of the nonlinear circuit block 1100, an output port of the first clock amplifier block 1410, and an output port of the second clock amplifier block 1420 are connected to connectors 1010, 1030 and 1040, respectively.

By doing so, data signals of different data rates are applied to the common input connector 1010 and respective clock signals corresponding to the input data signals are selective obtained from the output connector 1030 or 1040.

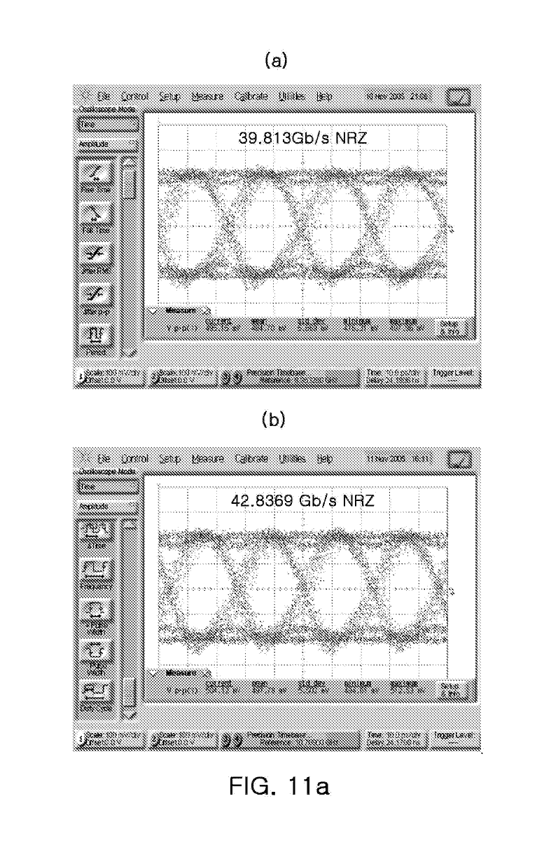

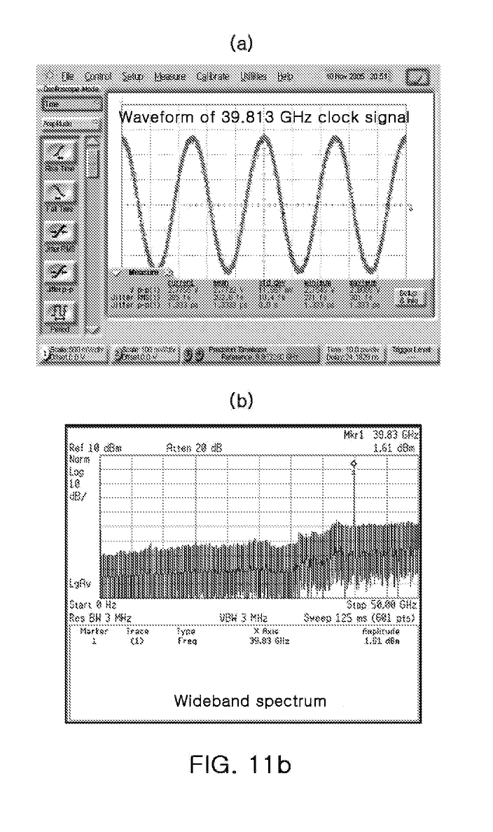

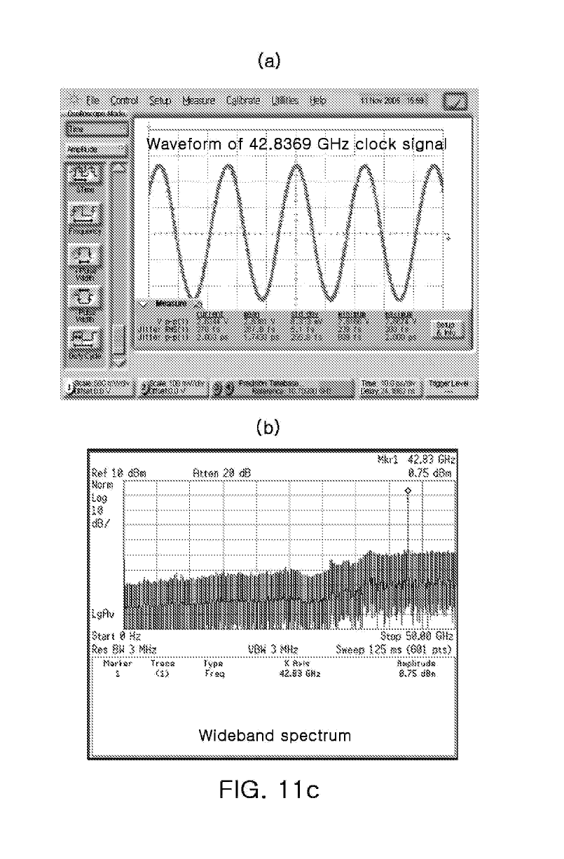

FIGS. 11A through 11C are graphs illustrating the results of testing the multi-mode open-loop type clock extraction apparatus according to the present invention. FIGS. 11A(a) and 11A(b) respectively illustrate a 39.813 Gbit/s NRZ electrical signal and a 42.8369 Gbit/s NRZ electrical signal that are applied to the multi-mode open-loop type clock extraction apparatus illustrated in FIG. 10. FIGS. 11B(a) and 11B(b) respectively illustrate the waveform and spectrum of a clock signal that is output from a 39.813 GHz output port of the multi-mode open-loop type clock extraction apparatus when a 39.813 Gbit/s NRZ electrical signal of FIG. 11A(a) is applied to the input connector 1010 of FIG. 10. FIGS. 11C(a) and 11C(b) respectively illustrate the waveform and spectrum of a clock signal that is output from a 42.8369 GHz output port of the multi-mode open-loop type clock extraction apparatus when a 42.8369 Gbit/s NRZ electrical signal of FIG. 11A(b) is applied to the input connector 1010 of FIG. 10.

It can be seen from the waveform illustrated in FIG. 11B (a) that a good-quality clock signal (39.813 GHz) with an RMS output jitter value of 285 fs is output. In addition, it can be seen from the spectrum illustrated in FIG. 11B(b) that a clock frequency component is just 39.813 GHz and there is no other signal.

Likewise, it can be seen from the waveform illustrated in FIG. 11C (a) that a good-quality clock signal (42.8369 GHz) with an RMS output jitter value of 270 fs is output. In addition, it can be seen from the spectrum illustrated in FIG. 11C (b) that a clock frequency component is just 42.8369 GHz and there is no other signal.

Although only the case where two different data signals of different data rates are inputted has been taken as an example, the present invention is not limited to this. That is, N number of data signals of different data rates may be inputted and clock signals suitable for the respective data rates can be extracted from the data signals. In this case, a length difference between the first and second transmission lines in the nonlinear circuit block illustrated in FIG. 6 satisfies Equation (2) below.

$$\vert {L}_{2} - {L}_{1} \vert ⇔ \frac{1}{2} ( \frac{{T}_{max} + {T}_{min}}{2} ) \qquad ( 2 )$$

In this case, it is necessary that the power divider block 420 or 510 is a 1: N power divider that divides an input data signal into N number of signals. It is also necessary that the multi-mode open-loop type clock extraction apparatus includes N number of band-pass filter blocks and N number of clock amplifier blocks. The center operating frequencies of the band-pass filter blocks and the clock amplifier blocks vary depending on the data rates of the data signals.

As described above, the use of the multi-mode open-loop type clock extraction apparatus using passive band-pass filters makes it possible to extract clock signals suitable for two different data rates. Accordingly, even when two different data signals of different data rates are inputted to a receiver of an optical transmission system, it is unnecessary to replace a clock extraction apparatus or a band-pass filter block of the clock extraction apparatus. Also, it is possible to achieve miniaturization by integration.

In addition, it is possible to extract clock signals corresponding to data signals of different data rates using a single clock extraction apparatus.

While the present invention has been described with reference to the particular illustrative embodiments and the accompanying drawings, it is not to be limited thereto but will be defined by the appended claims. It is to be appreciated that those skilled in the art can substitute, change or modify the embodiments into various forms without departing from the scope and spirit of the present invention.

What is claimed is:

1. A multi-mode open-loop type clock extraction apparatus comprising:
a power divider block for dividing an input data signal into two data signals;
a first band-pass filter block for extracting a first clock frequency component contained in the data signal output from the power divider;
a second band-pass filter block for extracting a second clock frequency component contained in the data signal output from the power divider;
a first amplifier block for amplifying the first clock frequency component extracted by the first band-pass filter block; and
a second amplifier block for amplifying the second clock frequency component extracted by the second band-pass filter block.

2. The multi-mode open-loop type clock extraction apparatus according to claim 1, further comprising a nonlinear circuit block for generating, from two types of data signals with different data rates, clock frequency components corresponding to each data rate.

3. The multi-mode open-loop type clock extraction apparatus according to claim 1, wherein the power divider block is a Wilkinson-type power divider or a resistive T-shaped power divider formed on a microwave substrate.

4. The multi-mode open-loop type clock extraction apparatus according to claim 1, wherein the first band-pass filter block and the second band-pass filter block are passive band-pass filters including dielectric resonator filters.

5. The multi-mode open-loop type clock extraction apparatus according to claim 4, wherein the dielectric resonator filter comprises:
a base plate;
a microwave substrate attached on the top surface of the base plate;
an input transmission line and an output transmission line disposed on the top surface of the microwave substrate such that the input/output transmission lines are arranged in a straight line;
a disc-type dielectric resonator disposed between the input transmission line and the output transmission line; and
a metal cover having a small internal space formed therein and being coupled with the base plate to cover the input transmission line, the output transmission line, and the disc-type dielectric resonator.

6. The multi-mode open-loop type clock extraction apparatus according to claim 2, wherein the nonlinear circuit block comprises exclusive-OR device for performing exclusive OR logic operation of data signals delayed by different time intervals to generate a clock frequency component from an input NRZ data signal, where the time difference between the delayed data signals is set to the half of the average time period of two NRZ input data signals with different data rates.

7. The multi-mode open-loop type clock extraction apparatus according to claim 6, wherein the nonlinear circuit block further comprises an amplifier amplifying an output signal of the exclusive-OR device.

8. The multi-mode open-loop type clock extraction apparatus according to claim 1, wherein the respective blocks are implemented on a microwave substrate, the I/O connections between respective blocks are made by a bonding technique, and the total blocks are packaged into a single module.

9. The multi-mode open-loop type clock extraction apparatus according to claim 1, wherein the first clock amplifier block and the second clock amplifier block are monolithic microwave IC (MMIC) amplifiers.

10. A multi-mode open-loop type clock extraction apparatus comprising:
a 1:N power divider block for dividing one of N number of data signals with various data rates into N number of data signals, where N is a natural number equal to or greater than 2;
N number of band-pass filter blocks connected respectively to output ports of the 1:N power divider and having center frequencies in pass-band corresponding to N number of data rates in order to extract the respective clock signals from data signals with N number of data rates; and
N number of amplifier blocks connected respectively to the output ports of band-pass filter blocks to amplify the respective clock signals extracted from the band-pass filter blocks.

11. The multi-mode open-loop type clock extraction apparatus according to claim 10, further comprising a nonlinear circuit block for generating, from data signals with N number of data rates, the respective clock frequency components corresponding to the data rates.

12. The multi-mode open-loop type clock extraction apparatus according to claim 11, wherein the nonlinear circuit block performs exclusive-OR logic operation of the data signals delayed by different time intervals to generate a clock frequency component from an input NRZ data signal, where the time difference between the delayed data signals is set to the half of the average time period of the data signals with the maximum data rate and the data signal with the minimum data rate.
